(19) United States
(12) Patent Application Publication
(10) Pub. No.: US 2025/0324783 A1
(43) Pub. Date: Oct. 16, 2025

(54) Image Sensor with Visible Light and Short Wave Infrared Detection

(71) Applicant: SEMICONDUCTOR COMPONENTS INDUSTRIES, LLC, Scottsdale, AZ (US)

(72) Inventors: Swarnal BORTHAKUR, Boise, ID (US); Jon DALEY, Boise, ID (US)

(73) Assignee: SEMICONDUCTOR COMPONENTS INDUSTRIES, LLC, Scottsdale, AZ (US)

(21) Appl. No.: 18/637,256

(22) Filed: Apr. 16, 2024

(51) Int. Cl. H01L 27/146

(52) U.S. Cl. CPC H10F 39/193; H10F 39/182; H10F 39/806; H10F 39/8063; H10F 39/8067; H10F 39/807; H10F 39/811

(57) ABSTRACT

An image sensor pixel is provided that includes a semiconductor substrate having a front surface and a back surface, a photosensitive element formed in the front surface of the semiconductor substrate and configured to sense light in a first range of wavelengths, an interconnect stack formed on the front surface of the semiconductor substrate, and a phase change resistor formed in the interconnect stack and configured to sense light in a second range of wavelengths different than the first range of wavelengths. The phase change resistor can include phase change material embedded within one or more resonant cavities interposed between a transparent conductor and a reflective conductor in the interconnect stack. Incoming light can enter through the back surface of the substrate and can be reflected internally within the one or more resonant cavities, resulting in the generation of heat and causing the phase change material to conduct current.

### BACKGROUND

Image sensors are commonly used in electronic devices such as cellular telephones, cameras, computers, and automobiles to capture images. In a typical arrangement, an image sensor includes an array of image pixels arranged in pixel rows and pixel columns. Circuitry may be coupled to each pixel column for reading out image signals from the image pixels.

It is within this context that the embodiments described herein arise.

### BRIEF DESCRIPTION OF THE DRAWINGS

FIG. 1 is a diagram of an illustrative electronic device having an image sensor in accordance with some embodiments.

FIG. 2 is a diagram of an illustrative pixel array and associated row and column control circuitry for reading out image signals from an image sensor in accordance with some embodiments.

FIG. 3 is a cross-sectional side view of an illustrative image sensor having phase change resistors in accordance with some embodiments.

FIG. 4 is a cross-sectional side view of an illustrative phase change resistor having a resonant cavity in accordance with some embodiments.

FIG. 5 is plot illustrating how a resonant cavity can be tuned to a target wavelength in accordance with some embodiments.

FIG. 6 is top (plan) view showing how an image sensor pixel can include a plurality of resonant cavities in accordance with some embodiments.

FIG. 7 is a top (plan) view showing how image sensor pixels can have resonant cavities tuned for different wavelengths in accordance with some embodiments.

### DETAILED DESCRIPTION

Embodiments of the present technology relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds or thousands or millions of pixels (e.g., megapixels). Image sensors may include control circuitry such as circuitry for operating the pixels and readout circuitry for reading out image signals corresponding to the electric charge generated by the photosensitive elements.

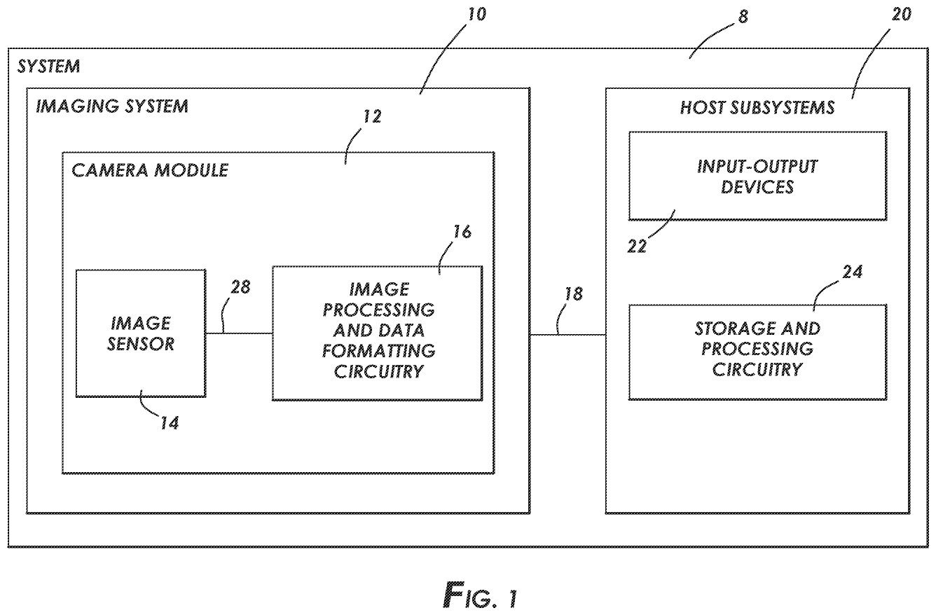

FIG. 1 is a diagram of an illustrative imaging and response system including an imaging system that uses an image sensor to capture images. System 8 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 8 may include an imaging system such as imaging system 10 and host subsystems such as host subsystem 20. Imaging system 10 may include camera module 12. Camera module 12 may include one or more image sensors 14, such as in an image sensor array integrated circuit, and one or more lenses. During image capture operations, each lens may focus light onto an associated image sensor 14. Image sensor 14 may include photosensitive elements (i.e., image sensor pixels) that convert the light into analog data. Image sensors may have any number of pixels (e.g., hundreds, thousands, millions, or more). A typical image sensor may, for example, have millions of pixels (e.g., megapixels).

Each image sensor in camera module 12 may be identical or there may be different types of image sensors in a given image sensor array integrated circuit. In some examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), and/or address circuitry.

Still and video image data from image sensor 14 may be provided to image processing and data formatting circuitry 16 via path 28. Image processing and data formatting circuitry 16 may be used to perform image processing functions such as data formatting, adjusting white balance and exposure, implementing video image stabilization, or face detection. Image processing and data formatting circuitry 16 may additionally or alternatively be used to compress raw camera image files if desired (e.g., to Joint Photographic Experts Group or JPEG format).

In one example arrangement, such as a system on chip (SoC) arrangement, sensor 14 and image processing and data formatting circuitry 16 are implemented on a common semiconductor substrate (e.g., a common silicon image sensor integrated circuit die). If desired, sensor 14 and image processing circuitry 16 may be formed on separate semiconductor substrates. For example, sensor 14 and image processing circuitry 16 may be formed on separate substrates that have been stacked.

Imaging system 10 may convey acquired image data to host subsystem 20 over path 18. Host subsystem 20 may include input-output devices 22 and storage processing circuitry 24. Host subsystem 20 may include processing software for detecting objects in images, detecting motion of objects between image frames, determining distances to objects in images, or filtering or otherwise processing images provided by imaging system 10. For example, image processing and data formatting circuitry 16 of the imaging system 10 may communicate the acquired image data to storage and processing circuitry 24 of the host subsystems 20.

If desired, system 8 may provide a user with numerous high-level functions. In a computer or cellular telephone, for example, a user may be provided with the ability to run user applications. For these functions, input-output devices 22 of host subsystem 20 may include keypads, input-output ports, buttons, and displays and storage and processing circuitry 24. Storage and processing circuitry 24 of host subsystem 20 may include volatile and/or nonvolatile memory (e.g., random-access memory, flash memory, hard drives, solid-state drives, etc.). Storage and processing circuitry 24 may additionally or alternatively include microprocessors, microcontrollers, digital signal processors, and/or application specific integrated circuits.

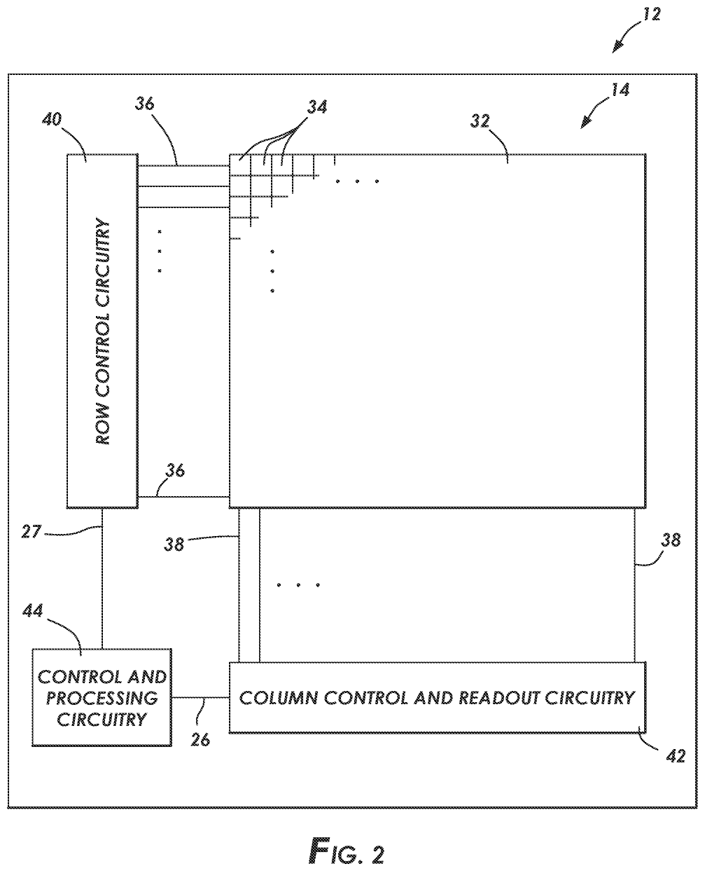

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic) may be part of image processing and data formatting circuitry 16 in FIG. 1 or may be separate from circuitry 16. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuits 42 via data path 26.

Row control circuitry 40 may receive row addresses from control and processing circuitry 44 and may supply corresponding row control signals to image pixels 34 over one or more control paths 36. The row control signals may include pixel reset control signals, charge transfer control signals, blooming control signals, row select control signals, dual conversion gain control signals, or any other desired pixel control signals.

Column control and readout circuitry 42 may be coupled to one or more of the columns of pixel array 32 via one or more conductive lines such as column lines 38. A given column line 38 may be coupled to a column of image pixels 34 in image pixel array 32 and may be used for reading out image signals from image pixels 34 and for supplying bias signals (e.g., bias currents or bias voltages) to image pixels 34. In some examples, each column of pixels may be coupled to a corresponding column line 38. For image pixel readout operations, a pixel row in image pixel array 32 may be selected using row driver circuitry 40 and image data associated with image pixels 34 of that pixel row may be read out by column readout circuitry 42 on column lines 38. Column readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, or column memory for storing the readout signals and any other desired data. Column control and readout circuitry 42 may output digital pixel readout values to control and processing logic 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure. Features described herein as rows may be arranged vertically and features described herein as columns may be arranged horizontally.

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels. The red, green, and blue image sensor pixels may be arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another example, broadband image pixels having broadband color filter elements (e.g., clear color filter elements) may be used instead of green pixels in a Bayer pattern. These examples are merely illustrative and, in general, color filter elements of any desired color (e.g., cyan, yellow, red, green, blue, etc.) and in any desired pattern may be formed over any desired number of image pixels 34.

Image sensors typically include imaging pixels configured to sense visible light (e.g., light in the visible spectrum from about 380 to 700 nanometers). Certain imaging applications have adopted near infrared (NIR) sensors that include imaging pixels configured to sense NIR light in the near infrared spectrum from about 750 to 1000 nanometers (nm). NIR sensing can, however, require emitting NIR light in the range of 750-1000 nm, which, if care is not taken, can cause harm to human eyes.

For eye safety reasons, image sensors configured to detect short wave infrared (SWIR) light are provided (e.g., for sensing light in the SWIR spectrum from about 1000 to 3000 nm). Such type of imagers can also include an SWIR emitter configured to output light within the SWIR range. As an example, an SWIR emitter can a high power laser having a wavelength of 1550 nm. Such high power emission can also enable light-based ranging operations for longer distances. Dedicated SWIR image sensors can be costly.

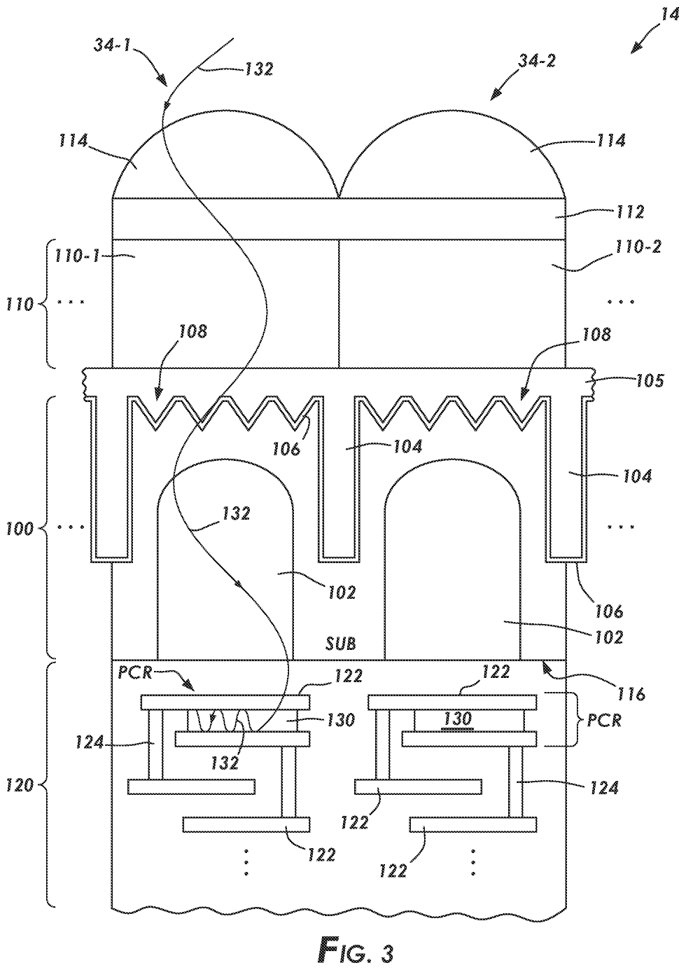

In accordance with an embodiment, an image sensor 14 is provided that includes image sensor pixels configured to provide both visible light detection and SWIR detection capabilities. The use of imaging pixels to provide dual detection functionality is technically advantageous and beneficial to dramatically reduce the cost of image sensors. FIG. 3 is a cross-sectional side view of an illustrative image sensor 14 having photodiodes configured to sense visible light and phase change resistors configured to sense SWIR light.

As shown in FIG. 3, image sensor 14 can include a substrate such as a p-type (p-doped) semiconductor substrate 100, photosensitive elements such as photodiodes 102 formed in (at) a first (front) surface of semiconductor substrate 100 such as surface 116, and an interconnect stack formed on the first surface 116. Pixel isolation structures such as deep trench isolation (DTI) structures 104 can be formed at a second (back) surface, opposing the first surface, of substrate 100. Deep trench isolation structures 104 formed at the back surface of substrate 100 are thus sometimes referred to as backside DTI (BDTI) structures 104. Backside DTI structures 104 can help provide enhanced electrical isolation between adjacent photodiodes/pixels. Backside DTI structures 104 may be formed only partially through substrate 100 as shown in the example of FIG. 3 or can be formed entirely through substrate 100 (e.g., extending from the back surface of substrate 100 down to front surface 116).

The BDTI structures 104 can be formed from silicon dioxide or other suitable dielectric material. This dielectric material may also cover the back surface of semiconducting substrate 100, as shown by dielectric layer 105. Layer 105 is sometimes referred to as a backside dielectric layer. An additional liner such as layer 106 can optionally be formed at the interface between semiconducting substrate 100 and the backside dielectric material. Layer 106 can be formed from high-k dielectric material such as aluminum oxide (Al₂O₃), hafnium oxide (HfO₂), tantalum oxide (Ta₂O₅), and/or other dielectric materials to help prevent the generation of dark current at the back surface of semiconductor substrate 100. Layer 106 is therefore sometimes referred to as a high-k dark current reduction liner.

An array of color filter structures may be formed on backside dielectric layer 105. In the example of FIG. 3, a first color filter element 110-1 is formed over a first photodiode 102, whereas a second color filter element 110-2 is formed over a second photodiode 102. The color filter elements may be part of a color filter array (CFA) 110 having red color filter elements, green color filter elements, blue color filter elements, cyan color filter elements, magenta color filter elements, yellow color filter elements, black color filter elements, clear (broadband) color filter elements, some combination of these color filter elements, and/or other color filter elements. The use of CFA 110 is optional and can be omitted for monochrome image sensors. A planarization layer such as planarization layer 112 may be formed on color filter array 110.

An array of microlens structures 114 may be formed over the color filter array 110. Each microlens 114 may be configured to direct incoming light 132 towards a corresponding photodiode 102. Each optical stack including at least a microlens structure 114, a color filter element 110, and a photodiode 102 may be referred to as an image sensor or imaging pixel 34. The example of FIG. 3 shows a first image sensor pixel 34-1 and an adjacent second image sensor pixel 34-2. Visible light traversing through a pixel 34 can be absorbed by photodiode 102. Thus, each image sensor pixel 34 can be configured to sense visible light so that the overall image sensor 14 can output a full resolution color image. Such image sensor configuration in which light enters semiconductor substrate 100 from the back surface is sometimes referred to as a backside illuminated (BSI) image sensing device.

If desired, each pixel 34 can optionally include light scattering structures such as light scattering structures 108 formed at the back surface of semiconducting substrate 100. Light scattering structures 108 can be formed from backside dielectric layer 105. Light scattering structures 108 can have slanted or angled edges or vertical edges (not slanted), relative to the plane of surface 116, configured to scatter incoming light to enable near infrared (NIR) detection by pixels 34. Light scattering structures 108 are therefore sometimes referred to as NIR light scattering structures. Configured in this way, each image sensor pixel 34 can be further configured to sense NIR light so that the overall image sensor 14 can output a full resolution near infrared image.

An interconnect stack such as interconnect stack 120 can be formed on semiconductor substrate 100. Interconnect stack 120 may include alternating routing layers and via layers formed within dielectric material such as silicon dioxide. Each routing layer can include conductive (metal) routing paths such as metal routing structures 122 formed in a layer of dielectric material. Each via layer can include conductive (metal) vias such as metal via structures 124 formed in a layer of dielectric material. Interconnect stack 120 is therefore sometimes referred to as a dielectric stack. Dielectric stack 120 may include at least two metal routing layers, at least three metal routing layers, four or more metal routing layers, five to ten metal routing layers, more than ten metal routing layers, or other number of conductive routing layers. The conductive routing structures 122 and the conductive via structures 124 can be formed from copper, indium tin oxide (ITO), aluminum, tungsten, titanium, gold, silver, nickel, a metal alloy, a combination of metals, and/or other types of conductive material. The metal routing structures 122 and the metal via structures 124 can form an electrical network for interconnecting together various components within pixels 34 and for coupling image signals obtained from pixels 34 to corresponding image signal processing circuitry or other off-chip components.

In accordance with some embodiments, each pixel 34 may include a resistor such as a phase change resistor PCR formed within interconnect stack 120. In the example of FIG. 3, the phase change resistor PCR of pixel 34-1 may include a resonant cavity 130 sandwiched or interposed between two conductive routing layers 122. FIG. 4 is a cross-sectional side view of an illustrative phase change resistor PCR. As shown in FIG. 4, resistor PCR has a first conductor 122′, a second conductor 122″, and a resonant cavity 130 disposed between conductors 122′ and 122″. First conductor 122′ may be a transparent conductive layer formed from indium tin oxide (ITO), other conductor configured to pass at least SWIR light, or other transparent conductor. Second conductor 122′ may be a reflective conductive layer formed from tantalum, copper, a combination of tantalum and copper, other conductor configured to reflect at least SWIR light, or other reflective conductor.

Resonant cavity 130 may have a cavity depth or thickness Tcavity that is determined by the distance between metal conductors 122′ and 122″. Resonant cavity 130 may include additional resonant cavity reflectors such as a first resonant cavity reflector 150-1 and a second resonant cavity reflector 150-2. First resonant cavity reflector 150-1 may be formed on transparent conductor 122′ within resonant cavity 130. First resonant cavity reflector 150-1 may include alternating layers of different refractive indices. As an example, first resonant cavity reflector 150-1 can include alternating silicon dioxide and amorphous silicon layers forming a first Distributed Bragg Reflector (DBR). On the other side, second resonant cavity reflector 150-2 may also include alternating layers of different refractive indices. As an example, second resonant cavity reflector 150-2 can include alternating silicon dioxide and amorphous silicon layers forming a second Distributed Bragg Reflector (DBR). If desired, other types of structures configured to reflect SWIR light can be provided within resonant cavity 130.

Phase change material such as phase change material 152 may be disposed within resonant cavity 130 between the resonant cavity reflectors 150-1 and 150-2 and between conductors 122′ and 122″. Phase change material (PCM) 152 may refer to and be defined herein as a substance that can change from one phase to another depending on external conditions like elevated temperature or electric field. As an example, phase change material 152 may be germanium telluride (GeTe), antimony telluride (SbTe), vanadium oxide (VO₂), silver selenide (Ag₂Se), indium antimony telluride (InSbTe), other phase change material that can alternate between an amorphous and crystalline state, some combination of these materials, or other suitable phase change material. A portion of the phase change material such as portion 153 may be coupled to transparent conductor 122′. Phase change material 152 may be coupled to second conductor 122′ through a conductive via 124″. Conductive via 124″ may optionally be formed from the same material as layer 122″ or can be formed from other conductive material. Other portions of the resonant cavity 130 may be filled with dielectric material 121. Configured in this way, current can flow between conductors 122′ and 122″ in response to a sufficient amount of heat being generated within resonant cavity 130.

The example of FIG. 4 in which the first conductor 122′ makes direct contact with the phase change material 152 via extending portion 153 is illustrative. As another example, the phase change material 152 may be directly coupled to reflective conductor 122″ via a portion of the phase change material that extends down towards conductor 122″. In such an arrangement, a conductive via, optionally formed from the same material as layer 122′, can electrically couple layer 122′ to the phase change material 152. As another example, the phase change material 152 may have a first portion such as portion 153 that extends towards transparent conductor 122′ and a second portion that extends towards reflective conductor 122″. As another example, the phase change material 152 may be coupled to the reflective conductor 122″ through a via such as via 124″ and may be coupled to the transparent conductor 122′ through another via formed from the same material as layer 122′. If desired, other ways for connecting the two opposing terminals of the phase change resistor PCR can be employed.

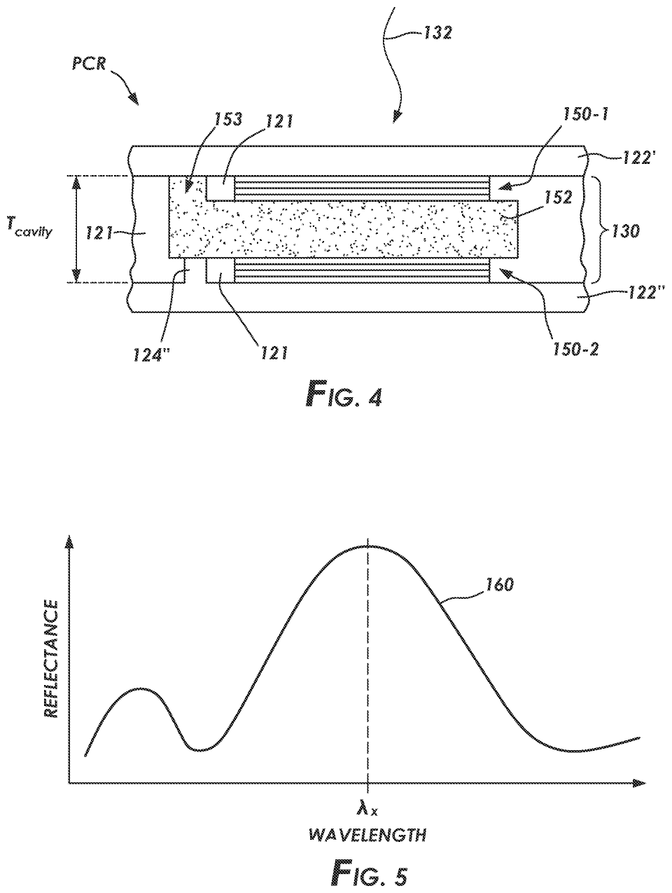

Resonant cavity 130 may be configured or tuned for one or more SWIR wavelengths. FIG. 5 is plot illustrating how resonant cavity 130 can be tuned to a target wavelength λx. As shown in FIG. 5, curve 160 plots the reflectance of resonant cavity 130 as a function of wavelength. Reflectance curve 160 can have a peak that is aligned to the target wavelength λx, which can be equal to 1550 nm, 2000 nm, 2500 nm, or other target wavelength in the SWIR spectrum in the range of 1000 to 3000 nm. The thickness of each layer within first resonant cavity reflector 150-1, the thickness of each layer within second resonant cavity reflector 150-2, and/or optionally the thickness Tcavity of resonant cavity 130 can be selected to align the peak reflectance of curve 160 to the target wavelength λx. As an example, the cavity thickness can be set equal to a quarter of the target wavelength λx to maximize the absorption of SWIR light by phase change material 152 within resonant cavity 130.

Referring back to the example of FIG. 3, incoming SWIR light 132 can be focused by microlens 114 and subsequently pass through substrate 100 entirely and arrive at resistor PCR. Photodiode 102 may not absorb SWIR wavelengths. SWIR light 132 arriving at resistor PCR may be reflected internally within resonant cavity 130, resulting in a phenomenon sometimes referred to as SWIR resonance. As an example, the SWIR light 132 arriving within resonant cavity 130 can bounce between the resonant cavity reflectors 150-1 and 150-2 at least five times, five to ten times, 10 to 20 times, or more than 20 times. Such SWIR resonance in cavity 130 can generate heat, which triggers a phase change in the phase change material 152 embedded within resistor PCR. For instance, the heat can cause phase change (PC) material 152 to change from an amorphous state to a crystalline state, which results in an increasing current flow between conductors 122′ and 122″ (see FIG. 4). The higher the heat generated within resonant cavity 130, the more crystalline the phase change material 152 becomes, resulting in material 152 becoming lower resistance to conduct current. The amount of current flow can thus depend on the amount of SWIR light 132 arriving at resistor PCR. In other words, the current is a function of the SWIR light intensity. Configured in this way, each image sensor pixel 34 can be further configured to sense SWIR light so that the overall image sensor 14 can output a full resolution short wave infrared image.

An image sensor arranged in this way is technically advantageous and beneficial since each image sensor pixel 34 can provide a plurality of wavelength sensing capabilities, including the ability to detect visible light, SWIR light, and/or optionally NIR light. An image sensor that is operable to produce full resolution color images, monochrome images, SWIR images, and NIR images can help dramatically reduce cost in a variety of applications. In one mode of operation, image sensor 14 can be configured to sense only visible light. In another mode of operation, image sensor 14 can be configured to sense only SWIR light. In such a mode, an external shutter can optionally be employed to block visible light to help increase the signal-to-noise ratio (SNR). In another mode of operation, image sensor 14 can be configured to sense only NIR light. In another mode of operation, image sensor 14 can be configured to simultaneously sense visible light, SWIR light, and NIR light. In another mode of operation, image sensor 14 can be configured to simultaneously sense visible light and SWIR light. In another mode of operation, image sensor 14 can be configured to simultaneously sense visible light and NIR light. In another mode of operation, image sensor 14 can be configured to simultaneously sense SWIR light and NIR light.

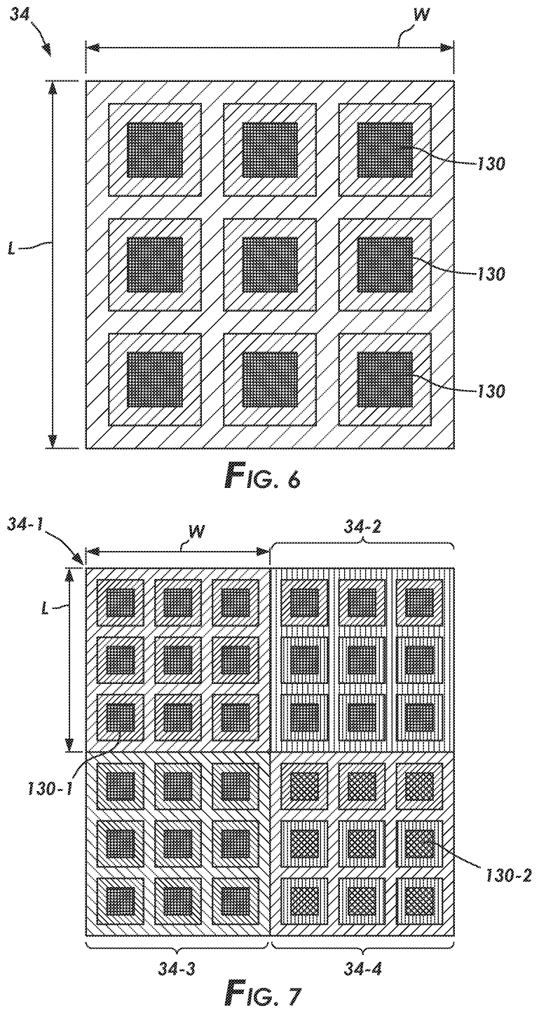

The embodiment of FIG. 3 in which each pixel 34 has one resonant cavity 130 is illustrative. In other embodiments, an image sensor pixel 34 can include more than one resonant cavity. FIG. 6 is top (plan) view showing how image sensor pixel 34 can include a plurality of resonant cavities. As shown in FIG. 6, image sensor pixel 34 have a length L and a width W. Pixel 34 of FIG. 6 has nine separate resonant cavities 130. The nine resonant cavities 130 may be physically coupled to the same transparent conductor (see conductor 122′ in FIG. 4) and to the same reflective conductor (see conductor 122″ in FIG. 4). Connected in this way, the multiple resonant cavities 130 collectively form one phase change resistor PCR. By packing in multiple smaller separate resonant cavities 130 in a given pixel area defined by length L and width W as opposed to a single larger, continuous resonant cavity within the given pixel area, heat can be more concentrated or localized in each of the smaller resonant cavities, which can help increase SWIR sensitivity and improve SNR.

As described above in connection with FIG. 5, a resonant cavity of a phase change resistor can be tuned for a certain target wavelength. In one embodiment, all pixels within an image sensor can include phase change resistors having resonant cavities tuned to a single target wavelength. FIG. 7 is a top (plan) view showing another embodiment where image sensor pixels 34 can have resonant cavities tuned for different wavelengths. FIG. 7 shows a group of four neighboring pixels, including a first pixel 34-1, a second pixel 34-2, a third pixel 34-3, and a fourth pixel 34-4. The first pixel 34-1 may have a first group of resonant cavities 130-1 tuned to a first wavelength, whereas the fourth pixel 34-4 may have a second group of resonant cavities 130-2 tuned to a second wavelength different than the first wavelength. As an example, resonant cavities 130-1 may be tuned for a first SWIR wavelength such as to 1100 nm, whereas resonant cavities 130-2 may be tuned for a second SWIR wavelength such as to 1200 nm.

If desired, pixel 34-2 can have another group of resonant cavities tuned to the first or second SWIR wavelength or another different target wavelength. Similarly, pixel 34-3 can have another group of resonant cavities tuned to the first or second SWIR wavelength or yet another different target wavelength. A 2×2 pixel array having four separate groups of resonant cavities tuned for four different SWIR wavelengths would have a quarter (¼) of the full SWIR resolution that would overwise be possible when all cavities are tuned to the same target wavelength. As another example, a 2×2 pixel array having four separate groups of resonant cavities tuned for two different SWIR wavelengths would have half (½) of the full SWIR resolution.

The embodiments described herein in which a particular resonant cavity is said to be tuned to a particular SWIR wavelength are exemplary. In general, a phase change resistor PCR can have one or more resonant cavities that are tuned for light having a target wavelength or a range of wavelengths. For example, a resonant cavity can exhibit SWIR resonance when receiving incoming light having wavelengths in a range of between 1450 to 1550 nm or other suitable subset of the SWIR range. The range for light that can cause a resonant cavity to resonate can be 0-10 nm, 0-20 nm, 0-50 nm, 50-100 nm, 100-200 nm, or other suitable range.

The foregoing is merely illustrative and various modifications can be made to the described embodiments. The foregoing embodiments may be implemented individually or in any combination.

What is claimed is:

1. An image sensor pixel comprising:
a semiconductor substrate having a first surface and a second surface opposing the first surface;
a photosensitive element formed in the first surface of the semiconductor substrate and configured to sense light in a first range of wavelengths;
an interconnect stack formed on the first surface of the semiconductor substrate; and
a phase change resistor formed in the interconnect stack and configured to sense light in a second range of wavelengths different than the first range of wavelengths.

2. The image sensor pixel of claim 1, wherein the phase change resistor comprises:
a first conductor formed in a first routing layer in the interconnect stack; and
a second conductor formed in a second routing layer in the interconnect stack, wherein the phase change resistor comprises a resonant cavity disposed between the first and second conductors.

3. The image sensor pixel of claim 2, wherein the first conductor comprises a transparent conductor, and wherein the second conductor comprises a reflective conductor.

4. The image sensor pixel of claim 2, wherein the phase change resistor further comprises:
a first resonant cavity reflector formed on the first conductor; and
a second resonant cavity reflector formed on the second conductor.

5. The image sensor pixel of claim 4, wherein the first resonant cavity reflector comprises a first set of alternating dielectric layers of different refractive indices, and wherein the second resonant cavity reflector comprises a second set of alternating dielectric layers of different refractive indices.

6. The image sensor pixel of claim 2, wherein the phase change resistor further comprises:
phase change material disposed between the first and second conductors, the phase change material being operable between an amorphous state and a crystalline state based on an amount of heat in the phase change material.

7. The image sensor pixel of claim 1, wherein the phase change resistor comprises a plurality of resonant cavities.

8. The image sensor pixel of claim 1, further comprising:
trench isolation structures formed in the second surface of the semiconductor substrate; and
light scattering structures formed between at least two of the trench isolation structures, the light scattering structures being configured to scatter light in a third range of wavelengths different than the first and second ranges of wavelengths.

9. The image sensor pixel of claim 8, further comprising:
a dielectric layer lining the trench isolation structures and the light scattering structures, the dielectric layer being configured to reduce dark current at the second surface of the semiconductor substrate.

10. The image sensor pixel of claim 1, further comprising:
a color filter element disposed on the second surface of the semiconductor substrate; and
a microlens disposed on the color filter element.

11. The image sensor pixel of claim 1, wherein the first range of wavelengths comprise one or more wavelengths in a visible spectrum, and wherein the second range of wavelengths comprise one or more wavelengths in a short wave infrared (SWIR) spectrum.

12. An image sensor pixel comprising:
a semiconductor substrate;
a dielectric stack formed on a first surface of the semiconductor substrate; and
a resistor formed within the dielectric stack, wherein the resistor comprises a resonant cavity configured to resonate in response to receiving light in a target range of wavelengths.

13. The image sensor pixel of claim 12, wherein the target range of wavelengths comprises wavelengths between 1000 and 3000 nanometers.

14. The image sensor pixel of claim 12, wherein the resistor further comprises phase change material embedded within the resonant cavity, and wherein the phase change material is operable between an amorphous state and a crystalline state.

15. The image sensor pixel of claim 12, wherein the resonant cavity is interposed between a transparent conductor and a reflective conductor within the dielectric stack.

16. The image sensor pixel of claim 15, wherein the resistor further comprises:
a first Distributed Bragg Reflector formed on the transparent conductor; and
a second Distributed Bragg Reflector formed on the reflective conductor.

17. The image sensor pixel of claim 12, further comprising:
a photodiode formed at the first surface of the semiconductor substrate; and
a plurality of backside deep trench isolation structures formed at a second surface of the semiconductor substrate.

18. The image sensor pixel of claim 12, further comprising:
light scattering structures formed at a second surface of the semiconductor substrate, the light scattering structures having slanted surfaces angled relative to the second surface.

19. An image sensor comprising:
a first imaging pixel having a first photodiode formed in a semiconductor substrate and having a first plurality of resonant cavities formed in an interconnect stack disposed on a surface of the semiconductor substrate; and
a second imaging pixel having a second photodiode formed in the semiconductor substrate and having a second plurality of resonant cavities formed in the interconnect stack.

20. The image sensor of claim 19, wherein the first plurality of resonant cavities is tuned to a first wavelength, and wherein the second plurality of resonant cavities is tuned to a second wavelength different than the first wavelength.
